(19) United States
(12) Patent Application Publication
(10) Pub. No.: US 2026/0050026 A1
(43) Pub. Date: Feb. 19, 2026

(54) INSPECTION JIG

(71) Applicant: Mitsubishi Electric Corporation, Tokyo (JP)

(72) Inventor: Toshihide OKA, Tokyo (JP)

(73) Assignee: Mitsubishi Electric Corporation, Tokyo (JP)

(21) Appl. No.: 19/103,531

(22) PCT Filed: Nov. 17, 2022
(86) PCT No.: PCT/JP2022/042646

§ 371 Date: Feb. 12, 2025

(51) Int. Cl. G01R 31/26; G01R 1/04

(52) U.S. Cl. CPC G01R 31/2601; G01R 1/0416

(57) ABSTRACT

An inspection jig for a semiconductor device provided with a plurality of lead pins includes: a contact portion in which contact electrodes are formed at troughs of first saw teeth; and a pressing portion in which second saw teeth are formed. During inspection of the semiconductor device, the contact portion is disposed such that the troughs of the first saw teeth correspond to the plurality of lead pins, the pressing portion is disposed such that the second saw teeth apply, to the plurality of lead pins, pressure toward the troughs of the first saw teeth, and the pressing portion applies pressure to the contact portion in a direction in which the plurality of lead pins extend, so that the pressing portion and the contact portion integrally move in the direction in which the plurality of lead pins extend.

### TECHNICAL FIELD

The present disclosure relates to an inspection jig for a semiconductor device provided with a plurality of lead pins.

### BACKGROUND ART

Some semiconductor devices are provided with a plurality of lead pins. The lead pins bend easily, and thus are sometimes bent already before a process of inspecting a semiconductor device due to various kinds of unintentional stress exerted thereon during an assembly process.

Patent Document 1 discloses an inspection jig which corrects bending of lead pins. This inspection jig corrects bending of lead pins by guiding the lead pins to recesses formed in a contact pusher.

### CITATION LIST

### PATENT DOCUMENT

Patent Document 1: Japanese Laid-Open Patent Publication No. 6-018614

### SUMMARY OF THE INVENTION

### Problem to be Solved by the Invention

However, in the inspection jig disclosed in Patent Document 1, the effect of correcting bending of lead pins is limited. In the inspection jig of Patent Document 1, when the lead pins are greatly bent, the lead pins cannot be guided to the recesses formed in the contact pusher. Thus, the bending of the greatly-bent lead pins needs to be corrected with another jig in advance. Therefore, a problem arises in that the time required for an inspection process increases.

The present disclosure has been made to solve the above problem, and an object of the present disclosure is to obtain an inspection jig capable of shortening the time required for an inspection process even when lead pins are greatly bent.

### Means to Solve the Problem

An inspection jig according to the present disclosure is for a semiconductor device provided with a plurality of lead pins and includes: a contact portion in which first saw teeth having the same pitch as the plurality of lead pins are formed, and contact electrodes are formed at troughs of the first saw teeth; and a pressing portion in which second saw teeth having the same pitch as the plurality of lead pins are formed, wherein during inspection of the semiconductor device, the contact portion is disposed such that the troughs of the first saw teeth correspond to the plurality of lead pins, the pressing portion is disposed such that the second saw teeth face the first saw teeth, and the second saw teeth apply, to the plurality of lead pins, pressure toward the troughs of the first saw teeth, so that the plurality of lead pins are electrically connected to the contact electrodes, and the pressing portion applies pressure to the contact portion in a direction in which the plurality of lead pins extend, so that the pressing portion and the contact portion integrally move in the direction in which the plurality of lead pins extend.

### Effect of the Invention

According to the present disclosure, an inspection jig capable of shortening the time required for an inspection process even when lead pins are greatly bent can be obtained.

### BRIEF DESCRIPTION OF THE DRAWINGS

FIG. 1 is a side view showing an inspection jig and a semiconductor device according to embodiment 1.

FIG. 2 is a top view showing the inspection jig and the semiconductor device according to embodiment 1.

FIG. 3 illustrates a process for inspecting the semiconductor device by using the inspection jig according to embodiment 1.

FIG. 4 illustrates a process for inspecting the semiconductor device by using the inspection jig according to embodiment 1.

FIG. 5 illustrates a process for inspecting the semiconductor device by using the inspection jig according to embodiment 1.

FIG. 6 is a side view showing an inspection jig and a semiconductor device according to embodiment 2.

FIG. 7 is a side view showing an inspection jig and a semiconductor device according to embodiment 3.

FIG. 8 illustrates a process for inspecting the semiconductor device by using the inspection jig according to embodiment 3.

FIG. 9 is a side view showing an inspection jig and a semiconductor device according to embodiment 4.

### DESCRIPTION OF EMBODIMENTS

### Embodiment 1

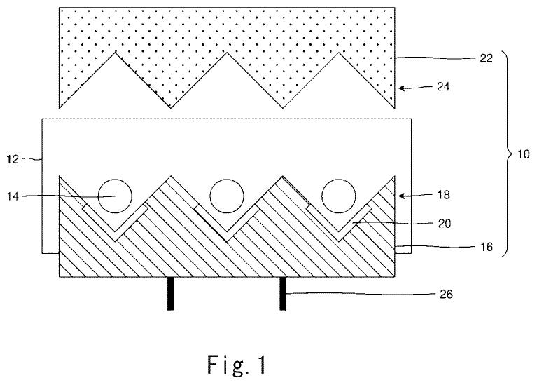

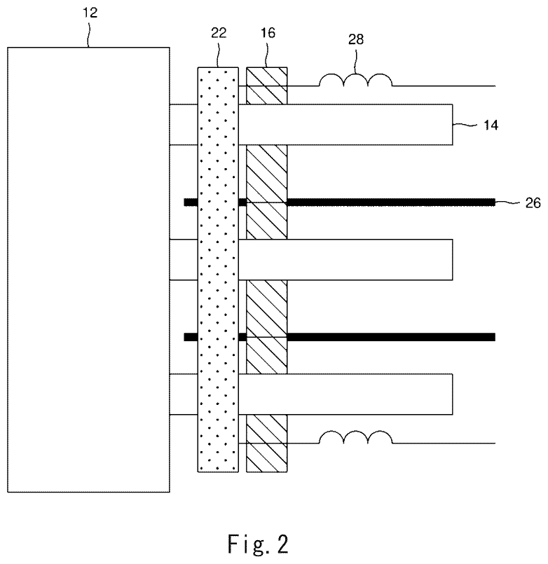

FIG. 1 and FIG. 2 show an inspection jig 10 according to embodiment 1. FIG. 1 and FIG. 2 are a side view and a top view of the inspection jig 10 and a semiconductor device 12 which is an inspection target. The inspection jig 10 includes a contact portion 16, a pressing portion 22, and a guide rail 26. The semiconductor device 12 is provided with a plurality of lead pins 14 arranged in a row so as to protrude to the outside.

In the contact portion 16, first saw teeth 18 having the same pitch as the plurality of lead pins 14 are formed. Here, the saw teeth mean a structure in which peaks and troughs are regularly repeated. Contact electrodes 20 are formed at troughs of the first saw teeth 18. The contact electrodes 20 are electrically connected to an inspection device (not shown), and are used for application of power supply voltage, transmission/reception of an electric signal, or the like.

In the pressing portion 22, second saw teeth 24 having the same pitch as the plurality of lead pins 14 are formed. A spring 28 is attached to the pressing portion 22, and by means of a contraction force of the spring 28, a force is applied in a direction (right direction in FIG. 2) in which the plurality of lead pins 14 extend.

The contact portion 16 is disposed on the guide rail 26. The contact portion 16 is movable along the guide rail 26 in the direction in which the plurality of lead pins 14 extend.

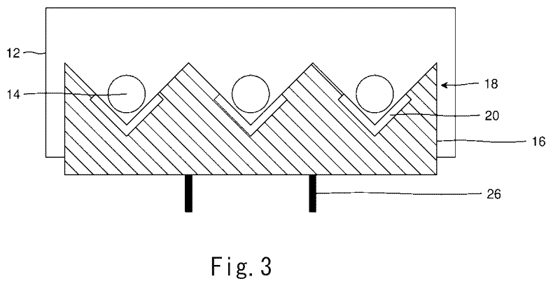

Here, inspection of a semiconductor device will be described. First, as shown in FIG. 3, during inspection of the semiconductor device, the contact portion 16 is disposed such that the troughs of the first saw teeth 18 correspond to the plurality of lead pins 14. Here, the state where the troughs of the first saw teeth 18 correspond to the plurality of lead pins 14 means that the direction (right-left direction in FIG. 3) in which the first saw teeth 18 are arranged is perpendicular to the direction (direction from back to front of the drawing of FIG. 3) in which the plurality of lead pins 14 extend, and that the plurality of lead pins 14 are brought into contact with, or are positioned in the vicinity of, the contact electrodes 20 formed at the troughs of the first saw teeth 18. At this time, the contact portion 16 is desirably disposed in a position near the roots, of the plurality of lead pins 14, where the lead pins are less bent. However, the position is not limited to the position near the roots as long as the troughs of the first saw teeth 18 can be disposed so as to correspond to the plurality of lead pins 14.

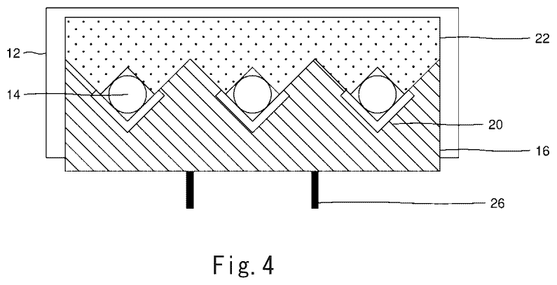

Next, as shown in FIG. 4, the pressing portion 22 is disposed such that the second saw teeth 24 face the first saw teeth 18 and the troughs of the second saw teeth 24 apply, to the plurality of lead pins 14, pressure toward the troughs of the first saw teeth 18. Accordingly, the plurality of lead pins 14 are electrically connected to the contact electrodes 20. At this time, a part of the pressing portion 22 is hidden backward of the contact portion 16 in the drawing of FIG. 4. FIG. 2 is a top view showing this state. As shown in FIG. 2, the pressing portion 22 is disposed closer to the roots of the plurality of lead pins 14 as compared to the contact portion 16.

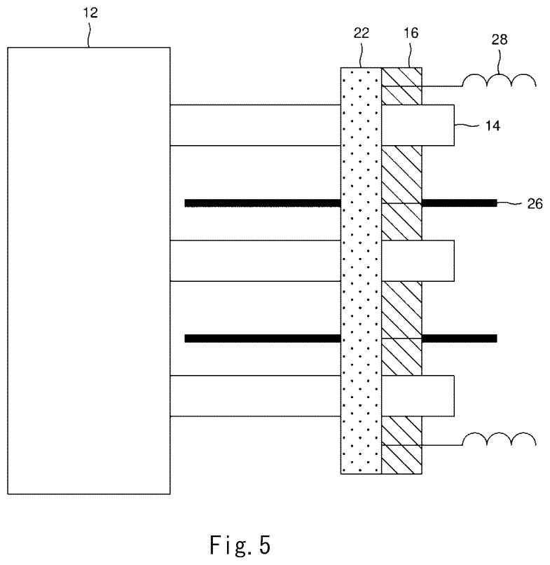

Subsequently, as shown in FIG. 5, the pressing portion 22 is moved in the direction in which the plurality of lead pins 14 extend by means of a contraction force of the spring 28. At this time, peaks of the second saw teeth 24 apply pressure to peaks of the first saw teeth 18 in the direction in which the plurality of lead pins 14 extend. Thus, the pressing portion 22 and the contact portion 16 integrally move along the guide rail 26 in the direction in which the plurality of lead pins 14 extend. With this movement, bending of the plurality of lead pins 14 is corrected. After that, the semiconductor device is inspected via the contact electrodes 20 electrically connected to the inspection device. It is noted that a stopper may be provided to the guide rail 26 so that the contact portion 16 is stopped by means of the stopper.

As described above, according to this embodiment, in a state where the troughs of the first saw teeth 18 correspond to the plurality of lead pins 14, and the troughs of the second saw teeth 24 apply pressure to the plurality of lead pins 14, the contact portion 16 and the pressing portion 22 are moved in the direction in which the plurality of lead pins 14 extend, and thus, it is possible to correct bending of the plurality of lead pins 14 even when the lead pins are greatly bent, and it is possible to execute inspection immediately after the correction. Consequently, the time required for an inspection process can be shortened.

It is noted that a force other than that of the spring may be used for moving the pressing portion 22. For example, the pressing portion 22 may be moved by using an electric motor or hydraulic pressure as a motive power source, or may be moved with a hand of an inspector.

### Embodiment 2

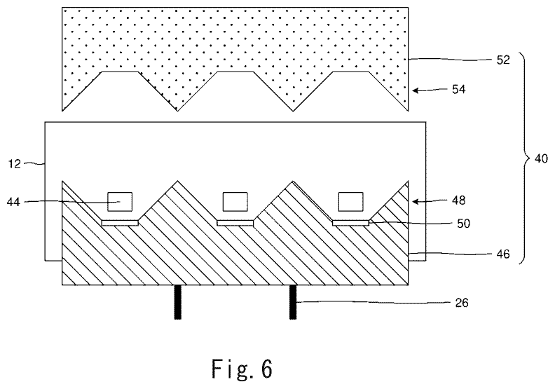

As shown in FIG. 6, in embodiment 2, unlike embodiment 1, a cross-sectional shape of each of a plurality of lead pins 44 is a rectangular shape having sides parallel to a direction (right-left direction in FIG. 6) in which the plurality of lead pins 44 are arranged, and troughs of first saw teeth 48 and second saw teeth 54 each have a flat surface shape. Here, the rectangular shape includes a square shape. In addition, the flat surface shape means the shape having a flat surface perpendicular to a direction (vertical direction in FIG. 6) in which teeth of the saw teeth protrude.

In this embodiment, the cross section of each of the plurality of lead pins 44 is a rectangular shape, and the troughs of the first saw teeth 48 and the second saw teeth 54 each have a flat surface shape, and thus, electrical connection between the plurality of lead pins 44 and contact electrodes 50 is good, and pressure which a pressing portion 52 applies to the plurality of lead pins 44 is uniform.

### Embodiment 3

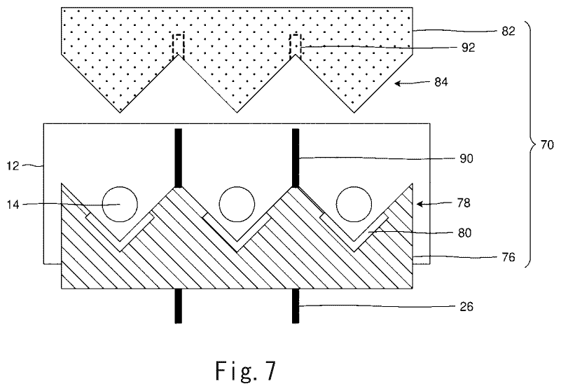

As shown in FIG. 7, in embodiment 3, unlike embodiment 1, guide pins 90 are formed at peaks of first saw teeth 78, and guide holes 92 are formed at troughs of second saw teeth 84. During inspection, peaks of the second saw teeth 84 apply pressure to a plurality of lead pins 14. In addition, the guide pins 90 are fitted to the guide holes 92 when the peaks of the second saw teeth 84 apply pressure to the plurality of lead pins 14.

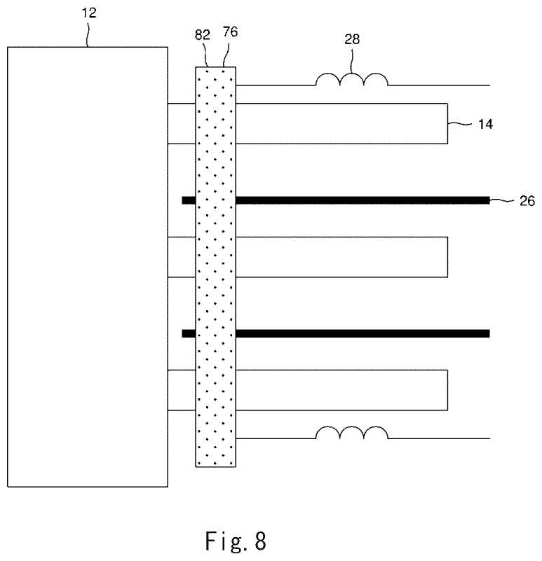

As shown in FIG. 8, when viewed from above, the first saw teeth 78 of a contact portion 76 and the second saw teeth 84 of a pressing portion 82 overlap in the direction in which the plurality of lead pins 14 extend. In FIG. 8, the contact portion 76 is hidden under the pressing portion 82.

During inspection, the guide pins 90 apply pressure to side surfaces of the guide holes 92, so that the pressing portion 82 and the contact portion 76 integrally move in the direction in which the plurality of lead pins 14 extend.

In this embodiment, when the peaks of the second saw teeth 84 apply pressure to the plurality of lead pins 14, the guide pins 90 are fitted to the guide holes 92, whereby the contact portion 76 and the pressing portion 82 are fixed. Consequently, the contact portion 76 and the pressing portion 82 can move stably when moving integrally.

### Embodiment 4

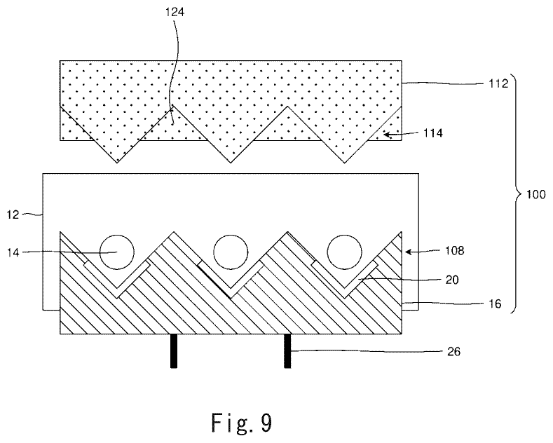

As shown in FIG. 9, in embodiment 4, unlike embodiment 3, there are no guide pins and guide holes, and at a pressing portion 112, a cover portion 124 that covers troughs of second saw teeth 114 is formed in back of the second saw teeth 114 when viewed from a direction (front side of the drawing of FIG. 9) in which the plurality of lead pins 14 extend. During inspection, the cover portion 124 applies pressure to peaks of first saw teeth 108, so that the pressing portion 112 and the contact portion 16 integrally move in the direction in which the plurality of lead pins 14 extend.

In this embodiment, the cover portion 124 moves while pressing the peaks of the first saw teeth 108, and thus can move stably.

### DESCRIPTION OF THE REFERENCE CHARACTERS

10, 40, 70, 100 inspection jig
12 semiconductor device
14, 4 plurality of lead pins
16, 46, 76 contact portion
18, 48, 78, 108 first saw teeth
20, 50, 80 contact electrode
22, 52, 82, 112 pressing portion
24, 54, 84, 114 second saw teeth
90 guide pin
92 guide hole
124 cover portion

1.-3. (canceled)

4. An inspection jig for a semiconductor device provided with a plurality of lead pins, the inspection jig comprising:
a contact portion in which first saw teeth having the same pitch as the plurality of lead pins are formed, and contact electrodes are formed at troughs of the first saw teeth; and
a pressing portion in which second saw teeth having the same pitch as the plurality of lead pins are formed, wherein
during inspection of the semiconductor device,
the contact portion is disposed such that the troughs of the first saw teeth correspond to the plurality of lead pins,
the pressing portion is disposed such that the second saw teeth face the first saw teeth, and the second saw teeth apply, to the plurality of lead pins, pressure toward the troughs of the first saw teeth, so that the plurality of lead pins are electrically connected to the contact electrodes,
the pressing portion applies pressure to the contact portion in a direction in which the plurality of lead pins extend, so that the pressing portion and the contact portion integrally move in the direction in which the plurality of lead pins extend,
guide pins are formed at peaks of the first saw teeth,
guide holes are formed at troughs of the second saw teeth, and
during inspection of the semiconductor device,
peaks of the second saw teeth apply pressure to the plurality of lead pins,
the guide pins are fitted to the guide holes when the peaks of the second saw teeth apply pressure to the plurality of lead pins, and
the guide pins apply pressure to side surfaces of the guide holes, so that the pressing portion and the contact portion integrally move in the direction in which the plurality of lead pins extend.

5. An inspection jig for a semiconductor device provided with a plurality of lead pins, the inspection jig comprising:
a contact portion in which first saw teeth having the same pitch as the plurality of lead pins are formed, and contact electrodes are formed at troughs of the first saw teeth; and
a pressing portion in which second saw teeth having the same pitch as the plurality of lead pins are formed, wherein
during inspection of the semiconductor device,
the contact portion is disposed such that the troughs of the first saw teeth correspond to the plurality of lead pins,
the pressing portion is disposed such that the second saw teeth face the first saw teeth, and the second saw teeth apply, to the plurality of lead pins, pressure toward the troughs of the first saw teeth, so that the plurality of lead pins are electrically connected to the contact electrodes,
the pressing portion applies pressure to the contact portion in a direction in which the plurality of lead pins extend, so that the pressing portion and the contact portion integrally move in the direction in which the plurality of lead pins extend,
a cover portion that covers troughs of the second saw teeth is formed at the pressing portion, and
during inspection of the semiconductor device,
peaks of the second saw teeth apply pressure to the plurality of lead pins, and
the cover portion applies pressure to peaks of the first saw teeth, so that the pressing portion and the contact portion integrally move in the direction in which the plurality of lead pins extend.
